(19) United States
(12) Patent Application Publication
(10) Pub. No.: US 2003/0104322 A1
(43) Pub. Date: Jun. 5, 2003

(54) Developing solution for photoresist

(76) Inventors: Yoshifumi Yamashita, Yamaguchi (JP); Satoshi Kawada, Yamaguchi (JP); Toru Nonaka, Yamaguchi (JP)

Correspondence Address: BIRCH STEWART KOLASCH & BIRCH, PO BOX 747, FALLS CHURCH, VA, 22040-0747, US

(21) Appl. No.: 10/130,628

(22) PCT Filed: Sep. 19, 2001
(86) PCT No.: PCT/JP01/08145

(30) Foreign Application Priority Data
Sep. 21, 2000 (JP) 2000-286508
Sep. 29, 2000 (JP) 2000-299049

(51) Int. Cl. G03F 7/32

(52) U.S. Cl. 430/331; 430/493

(57) ABSTRACT

A photoresist developer which is excellent in the wettability of a non-soluble portion of a photoresist after exposure and the solubility of a soluble portion and controls the dissolving speed of the non-soluble portion effectively.

This developer is prepared by adding a nonionic surfactant and a cationic surfactant to an alkali aqueous solution in a total amount of 10 to 5,000 ppm by weight.

### FIELD OF THE INVENTION

The present invention relates to a novel photoresist developer. More specifically, it relates to a photoresist developer which is excellent in the wettability of a non-soluble portion of a photoresist after exposure and the solubility of a soluble portion and controls the dissolving speed of the non-soluble portion effectively.

### DESCRIPTION OF THE PRIOR ART

For the production of semiconductor devices, semiconductor integrated circuits have been becoming higher in density and smaller in pattern width. For instance, in the step of lithography for forming a pattern, the light source of an exposure device has been shifting from a KrF excimer laser (248 nm) to an ArF excimer laser (198 nm) and further to an F₂ excimer laser (157 nm).

In this lithography step, a mask having a circuit pattern is used to transfer the circuit pattern to a photoresist formed on a wafer by exposure and then the exposed surface of the photoresist is contacted to a developer to dissolve an exposed portion in the developer in the case of a positive type and an unexposed portion in the developer in the case of a negative type. Then the remaining photoresist after the above development serves as a mask and the wafer as a base substrate is etched by plasma to form a circuit.

In the above lithography step, when an excimer laser is used as a light source, a chemically amplifying photoresist is generally used as the photoresist. As this chemically amplifying photoresist is used a composition comprising a resin whose solubility in a developer is controlled by masking a functional group contained in a base resin soluble in the developer with a protective group and an optically acid generating agent which generates an acid by exposure as essential ingredients.

When this chemically amplifying photoresist is applied to a substrate, an acid is generated from the optically acid generating agent by exposuring the photoresist with an excimer laser and a reaction for enabling the acid to disconnect the protective group is caused by baking after exposure. As a result, the base resin of the photoresist becomes soluble in an alkali aqueous solution, thereby making it possible to develop the photoresist with the alkali aqueous solution as a developer.

Meanwhile, the developer for the above photoresist is required to have high resolution. This resolution is expressed by the ratio of the developing speed of the exposed portion to the developing speed of the unexposed portion of the photoresist, that is, the developer selection ratio of the photoresist. A high selection ratio is important to obtain a fine photoresist pattern.

However, the above photoresist is hydrophobic. Since especially the non-soluble portion of the photoresist after exposure has high hydrophobic nature, the wettability of the portion with the developer which is an alkali aqueous solution is poor, whereby the developer is hardly contacted to a soluble portion due to the poor wettability of the non-soluble portion surrounding the soluble portion when the soluble portion forming a pattern is very small, with the result of the undevelopment of the base portion of the pattern.

The above problem is marked when puddle development is used in the production process of an integrated circuit.

As means of solving the above problem, a surfactant is added to a developer to improve the wettability of the non-soluble portion. Particularly, a developer prepared by adding a nonionic surfactant to an alkali aqueous solution is effective for chemically amplifying photoresists. It shows high wettability for the photoresist and is excellent in the solubility of the soluble portion of a photoresist after exposure, thereby making it possible to achieve high resolution.

However, the developer containing a nonionic surfactant still has a problem to be solved in order to obtain high reproducibility of a photoresist pattern. That is, the problem is that the developer has relatively high solubility for the non-soluble portion of the photoresist used as a mask in the subsequent etching step, therey making it impossible to ensure a sufficient film thickness after developing. This problem appears markedly these days when there is a tendency to reduce the thickness of a photoresist in order to improve the accuracy of a pattern.

In contrast to this, attempts have been made to control the solubility of the non-soluble portion by using a specific nonionic surfactant and its effect is obtained to a certain degree but this method is still unsatisfactory and further improvement is desired.

### SUMMARY OF THE INVENTION

It is therefore an object of the present invention to provide a photoresist developer which is excellent in the wettability of a non-soluble portion after exposure of a photoresist and the solubility of a soluble portion and controls the dissolving speed of the non-soluble portion effectively.

Other objects and advantages of the present invention will become apparent from the following description.

The inventors of the present invention have continued intensive studies to solve the above problem and have found that the above object can be attained by adding a nonionic surfactant and a cationic surfactant to an alkali aqueous solution. The present invention has been accomplished based on this finding.

That is, the present invention is a photoresist developer of an alkali aqueous solution which comprises a nonionic surfactant and a cationic surfactant in a total amount of 10 to 5,000 ppm by weight.

### DETAILED DESCRIPTION OF THE PREFERRED EMBODIMENT

Any alkali source known as a component of a photoresist developer may be used as an alkali source for the alkali aqueous solution in the present invention. Illustrative examples of the alkali source include primary, secondary and tertiary amines such as propylamine, butylamine, dibutylamine and triethylamine; cyclic bases containing carbon, nitrogen and optionally oxygen and/or sulfur such as pyrrole, pyrrolidine, pyrrolidone, pyridine, morpholine, pyrazine, piperidine, oxazole and thiazole; and quaternary ammonium bases such as tetramethylammonium hydroxide (to be abbreviated as TMAH hereinafter), tetraethylammonium hydroxide, tetrapropylammonium hydroxide, trimethylethylammonium hydroxide, trimethyl(2-hydroxyethyl)ammonium hydroxide, triethyl(2-hydroxyethyl)ammonium hydroxide, tripropyl(2-hydroxyethyl)ammonium hydroxide and trimethyl(1-hydroxypropyl)ammonium hydroxide. One or a mixture of two or more out of these alkali sources may be contained in the alkali aqueous solution.

Out of these, an alkali aqueous solution containing TMAH or trimethyl(2-hydroxyethyl)ammonium hydroxide is preferred.

The amount of the alkali source in the developer of the present invention, which is suitably selected according to the alkali source used, is preferably 0.1 to 10 wt %, more preferably 1 to 5 wt %.

When the amount of the alkali source is smaller than 0.1 wt %, the soluble portion (exposed portion in the case of a positive type) does not dissolve in the developer completely, thereby making it difficult to form a pattern (latent image). When the amount of the alkali source is larger than 10 wt %, the solubility of the non-soluble portion (unexposed portion in the case of a positive type) becomes high, thereby making it difficult to achieve the effect of the present invention.

The greatest feature of the present invention is that the above alkali aqueous solution contains both a nonionic surfactant and a cationic surfactant.

Since a developer prepared by adding a nonionic surfactant and no cationic surfactant to an alkali aqueous solution has the effect of improving the wettability of the non-soluble portion of the photoresist after exposure and surface tension on the non-soluble portion and can improve the solubility of the soluble portion, it can form a fine pattern. However, as the dissolving speed of the non-soluble portion is high, when the thickness of the photoresist is small, it is apprehended that part of a pattern formed by the non-soluble portion may be missing.

In contrast to this, in the present invention, surprisingly, the solubility of the non-soluble portion can be controlled extremely effectively by using a combination of a nonionic surfactant and a cationic surfactant as the composition of the developer almost without reducing the wettability of the non-soluble portion of the photoresist after exposure and the solubility of the soluble portion obtained by the nonionic surfactant.

In the present invention, any known nonionic surfactant may be used as the nonionic surfactant. Examples of the nonionic surfactants include polyoxyethylene alkyl ethers, polyoxyethylene polyoxypropylene alkyl ethers, polyoxyethylene alkylphenyl ethers, polyoxyethylene polyoxypropylene alkylphenyl ethers, polyoxyethylene glycols, polyoxyethylene polyoxypropylene glycols, polyoxypropylene glycols, polyoxyethylene fatty acid esters, polyoxyethylene sorbitan fatty acid esters, sorbitan fatty acid esters, glycerin fatty acid monoesters, cane sugar fatty acid esters, fatty acid alkanol amides, polyoxyethylene alkylamides, polyoxyethylene polyoxypropylene alkylamides, polyoxyethylene alkylamino ethers, polyoxyethylene polyoxypropylene alkylamino ethers, polyoxyethylene acetylene glycols, polyoxyethylene polyoxypropylene acetylene glycols and alkyl phosphoric acid ester salts. These surfactants may be used alone or in combination of two or more.

Out of these nonionic surfactants, preferred are polyoxyethylene polyoxypropylene alkyl ethers, polyoxyethylene polyoxypropylene alkylphenyl ethers, polyoxyethylene polyoxypropylene glycols and polyoxyethylene polyoxypropylene alkylamides.

Out of these, particularly preferred are nonionic surfactants represented by the following formulas (1) to (4):

R—O—(CH₂CH₂)ₙ—(CH(CH₃) CH₂)ₘ—OH (1)

R—COO—(CH₂CH₂)ₙ—(CH(CH₃)CH₂)ₘ—OH (2)

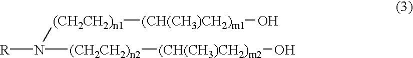 H—(CH₂CH₂)ₙ—(CH(CH₃)CH₂)ₘ—OH (4)

wherein R is a linear alkyl group having 4 to 18 carbon atoms; branched alkyl group represented by any one of the following formulas:

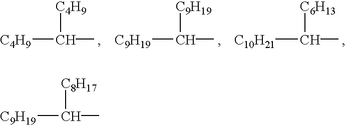

or a group selected from the group consisting of a phenyl group and alkylphenyl groups represented by the following formulas:

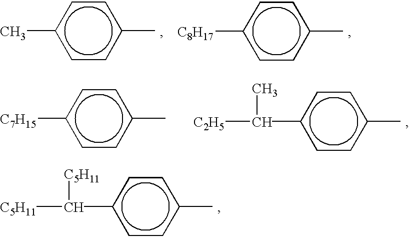

n, m, n1, n2, m1 and m2 are each an integer, n is an integer of 5 to 40, m is an integer of 2 to 30, n1+n2 is 5 to 40, and m1+m2 is 2 to 30.

In the present invention, specific examples of the compounds represented by the above formulas (1) to (4) are given below.

C₁₀H₂₁—O—(CH₂CH₂O)₉—(CH(CH₃)CH₂O)₄—OH

C₈H₁₇—O—(CH₂CH₂O)₁₆—(CH(CH₃)CH₂O)₁₄—OH

C₁₂H₂₅—O—(CH₂CH₂O)₉—(CH(CH₃)CH₂O)₄—OH

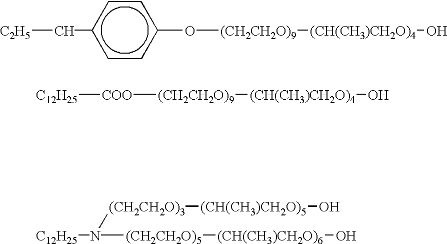

In the present invention, any known cationic surfactant may be used as the cationic surfactant used in combination with the above nonionic surfactant. Examples of the cationic surfactant include primary to quaternary alkylamines and salts thereof such as monoalkylamines and salts thereof, alkyltrimethylamines and salts thereof, and dialkyldimethylamines and salts thereof; imidazolinium and salts thereof, alkylbenzyldimethyl quaternary ammoniums and salts thereof, benzylpyridinium and salts thereof, alkylpyridiniums and salts thereof, and polyoxyethylene alkylbenzyl ammoniums and salts thereof. These surfactants may be used alone or in combination of two or more.

Out of these surfactants, particularly preferred are surfactants represented by the following formulas (5) to (8):

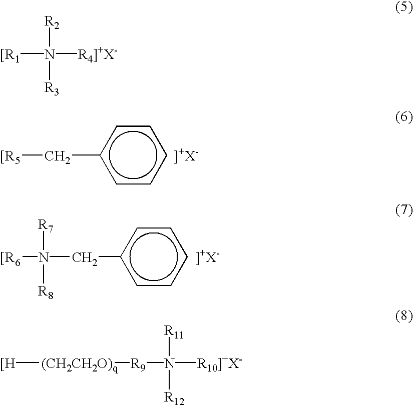

wherein R₁ to R₄, R₆ to R₈ and R₁₀ to R₁₂ are each independently hydrogen, methyl group or alkyl group having 4 to 15 carbon atoms, with the proviso that an alkyl group having 4 to 15 carbon atoms and hydrogen or methyl group are contained in a group of R₁ to R₄, a group of R₆ to R₈ and a group of R₁₀ to R₁₂, R₅ is a pyridinium group or phenyl group, R₉ is an alkylene group having 4 to 15 carbon atoms, q is an integer of 5 to 20, and X is OH, Cl, Br or I.

The above cationic surfactant is preferably such that the alkyl group contained is linear. Preferred examples of the cationic surfactant include compounds represented by the following formulas:

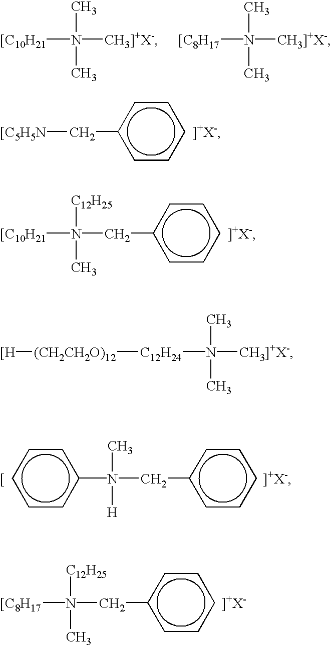

wherein X is OH, Cl, Br or I.

In the lithography step of the semiconductor production process, use of no halide is advantageous in suppressing the corrosion of a contacting metal such as a metal wire. Therefore, a hydroxide may be preferably used as the cationic surfactant.

In the present invention, the nonionic surfactant and the cationic surfactant are contained in the developer in a total amount of 10 to 5,000 ppm by weight, preferably 20 to 1,000 ppm by weight.

When the amount is smaller than 10 ppm by weight, the wettability of the photoresist and the surface tension on the photoresist may lower and when the amount is larger than 5,000 ppm by weight, bubbles may be generated considerably and adhered to the surface of the resist, thereby causing a development failure.

The weight ratio of the nonionic surfactant to the cationic surfactant is 5:95 to 95:5, preferably15:85 to 85:15. When the amount of the nonionic surfactant is smaller than 5 parts by weight based on 100 parts by weight of the total of the nonionic surfactant and the cationic surfactant, the above wettability and surface tension hardly improve and when the amount of the nonionic surfactant is larger than 95 parts by weight, the solubility of the non-soluble portion may become high.

The developer used in the present invention may contain known additives which are used in the conventional developers in limits not prejudicial to the object of the present invention.

The known additives include a surfactant, wetting agent, stabilizer and solubilizing aid. They are added alone or in combination of two or more.

The developer of the present invention may be used as a developer for known photoresists after exposure no matter whether they are of a positive or negative type if the soluble portion after exposure is soluble in the alkali aqueous solution. Particularly when the photoresist is a chemically amplifying photoresist, the effect of the developer is marked and the developer is preferred for that photoresist.

The above chemically amplifying photoresist is a composition comprising a resin whose solubility in a developer is controlled by masking a functional group contained in a base resin soluble in the developer with a protective group and an optically acid generating agent which generates an acid by exposure as essential ingredients as described above.

When a KrF or F₂ excimer laser is used, polyhydroxystyrene and derivatives thereof, styrene maleimide copolymer and derivatives thereof, hydroxystyrene-sulfone copolymer and derivatives thereof, and vinylphenol-methylvinylphenol copolymer and derivatives thereof may be used as the resin constituting the above photoresist.

When an Arf or F₂ excimer laser is used, adamantyl(methacrylate)-based and isobornyl methacrylate-based copolymers and derivatives thereof, t-butyl methacrylate-methyl methacrylate-naphthyl methacrylate tetrapolymer and derivatives thereof may be used.

Examples of the above protective group include t-butyloxycarbonyl group, t-butyl group, t-butoxy group, tetrahydropyranyl ether group, trimethylsilyl ether group and isopropyloxy group.

Examples of the above optically acid generating agent include triphenylsulfonium hexafluoroantimonate, isocyanurate halide, triazine halide, nitrobenzyl sulfonic acid esters, diazonaphthoquinone-4-sulfonic acid esters, alkylsulfonic acid esters, bisarylsulfonyl diazomethane, β-oxocyclohexylmethyl(2-norbornyl)sulfonium trifluoromethanesulfonic acid and cyclohexylmethyl(2-oxocyclohexyl)sulfonium trifluoromethanesulfonic acid.

Any known method such as immersion development or puddle development may be used as the development method using the developer of the present invention.

As means of contacting the developer to the photoresist, immersion development in which a substrate such as a silicon wafer having a photoresist layer formed thereon is immersed in the developer for a certain period of time, immersed in pure water and dried, puddle development in which the developer is dropped on the surface of a photoresist and left for a certain period of time, and the photoresist is rinsed with pure water and dried, and spray development in which a photoresist is sprayed with the developer, rinsed with pure water and dried may be suitably selected and used.

Thus, when a KrF excimer laser is used, a gate electrode having a line width of 0.14 μm and a hole having a diameter or side length of 0.14 μm can be formed well. When an ArF excimer laser is used, a gate electrode having a line width of 0.11 μm and a hole having a diameter or side length of 0.11 μm can be formed well. When an F₂ excimer laser is used, a gate electrode having a line width of 0.09 μm and a hole having a diameter or side length of 0.09 μm can be formed.

### EXAMPLES

The following examples and comparative examples are provided for the purpose of further illustrating the present invention but are in no way to be taken as limiting. Examples 1 to 10 and Comparative Examples 1 to 3

Developers were prepared by adding a surfactant shown in Table 1 in an amount shown in Table 1 to a 2.38 wt % aqueous solution of TMAH (of Tokuyama Corporation, trade name: SD-1). The surface tensions of the prepared developers were measured. The results are shown in Table 2.

Thereafter, a silicon wafer was prepared and its surface was cleaned with a mixture of sulfuric acid and hydrogen peroxide (volume ratio of 4:1). It was baked on a hot plate at 200° C. for 60 seconds. After baking, hexamethyldisilazane (HMDS) was applied to hydrophobilize the surface of the silicon wafer. Chemically amplifying positive photoresists A (t-Boc type), B (acetal type) and C (ESCAP type) for KrF excimer laser were applied to the silicon wafer with a spinner coater, prebaked under conditions shown in Table 3 and cooled. A 12×12 cm square portion was exposed to light from an ultraviolet lamp (7 μW) having a spectrum at 248 nm for 100 seconds. The amount of exposure was 7 mJ/cm². After exposure, it was post-baked under conditions shown in Table 3 after exposure.

Each of the above prepared developers was dropped on the non-soluble portion (unexposed portion) of the photoresist after the above treatment and the contact angle of the developer was measured with a contact angle meter. In this case, as the contact angle becomes smaller, the wettability becomes better. The results are shown in Table 2.

Further, after the thickness of the non-soluble portion of the photoresist was measured after the above treatment, the photoresist was immersed in the prepared developer for 60 seconds, rinsed with pure water and dried to measure the thickness of the remaining photoresist film. The difference between thickness before immersion and thickness after immersion was expressed as a “film thickness reduction” in Table 2.

Moreover, the exposed portion (soluble portion) was immersed in the prepared developer for 60 seconds, rinsed with pure water and dried. The development of the above exposed portion was observed visually and evaluated as ◯ when the square was completely developed and X when there was the residue. The results are shown in Table 2.

TABLE 1

| | blended nonionic surfactant | | blended cationic surfactant | |
|---|---|---|---|---|
| | | amount | | amount |
| | structural formula | (ppm) | structural formula | (ppm) |
| Ex. 1 | 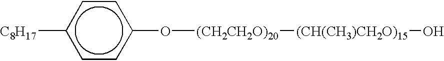 | 40 | 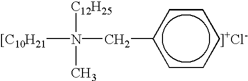 | 130 |
| Ex. 2 | C₁₂H₂₅—COO—(CH₂CH₂O)₉—(CH(CH₃)CH₂O)₄—OH | 100 | 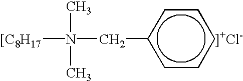 | 20 |
| Ex. 3 | C₁₀H₂₁—O—(CH₂CH₂O)₉—(CH(CH₃)CH₂O)₄—OH | 30 | 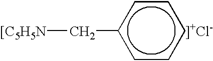 | 70 |
| Ex. 4 | 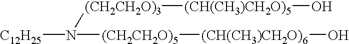 | 50 | 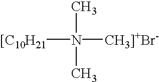 | 100 |
| Ex. 5 | H—(CH₂CH₂O)₂₅—(CH(CH₃)CH₂O)₃₀—OH | 120 | 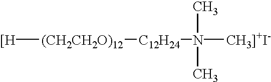 | 40 |
| Ex. 6 | 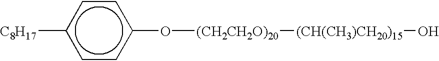 | 50 | 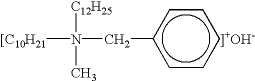 | 150 |
| Ex. 7 | C₁₂H₂₅—COO—(CH₂CH₂O)₉—(CH(CH₃)CH₂O)₄—OH | 90 | 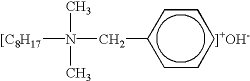 | 30 |
| Ex. 8 | C₁₀H₂₁—O—(CH₂CH₂O)₉—(CH(CH₃)CH₂O)₄—OH | 40 | 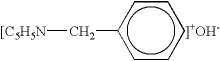 | 60 |
| Ex. 9 | 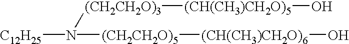 | 30 | 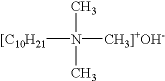 | 120 |
| Ex. 10 | H—(CH₂CH₂O)₂₅—(CH(CH₃)CH₂O)₃₀—OH | 100 | 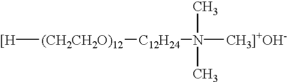 | 20 |
| C. Ex. 1 | nil | — | nil | — |
| C. Ex. 2 | C₁₂H₂₅—O—(CH₂CH₂O)₁₂—(CH(CH₃)CH₂O)₅—OH | 130 | nil | — |
| C. Ex. 3 | nil | — | 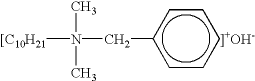 | 200 |

Ex.: Example
C. Ex.: Comparative Example

TABLE 2

| | | wettability of exposed | | | film thickness reduction of | | | | | |
|---|---|---|---|---|---|---|---|---|---|---|
| | surface | portion (degree) | | | unexposed portion (A) | | | development | | |
| | tension | resist A | resist B | resist C | resist A | resist B | resist C | resist A | resist B | resist C |
| Ex. 1 | 47.3 | 49 | 50 | 48 | 177 | 200 | 111 | ◯ | ◯ | ◯ |
| Ex. 2 | 42.2 | 46 | 46 | 46 | 160 | 188 | 105 | ◯ | ◯ | ◯ |
| Ex. 3 | 46.2 | 48 | 46 | 43 | 174 | 192 | 103 | ◯ | ◯ | ◯ |
| Ex. 4 | 44.7 | 45 | 45 | 44 | 163 | 199 | 100 | ◯ | ◯ | ◯ |
| Ex. 5 | 42.6 | 45 | 46 | 46 | 178 | 198 | 116 | ◯ | ◯ | ◯ |
| Ex. 6 | 45.2 | 52 | 51 | 47 | 181 | 210 | 121 | ◯ | ◯ | ◯ |
| Ex. 7 | 40.3 | 45 | 45 | 42 | 158 | 186 | 103 | ◯ | ◯ | ◯ |
| Ex. 8 | 42.7 | 47 | 45 | 44 | 170 | 190 | 101 | ◯ | ◯ | ◯ |
| Ex. 9 | 43.3 | 47 | 46 | 44 | 158 | 192 | 98 | ◯ | ◯ | ◯ |
| Ex. 10 | 41.8 | 46 | 47 | 47 | 176 | 197 | 110 | ◯ | ◯ | ◯ |
| C. Ex. 1 | 72.5 | 72 | 72 | 71 | 162 | 192 | 110 | X | X | X |
| C. Ex. 2 | 40.2 | 48 | 49 | 48 | 283 | 520 | 150 | ◯ | ◯ | ◯ |
| C. Ex. 3 | 70.4 | 68 | 67 | 68 | 161 | 190 | 100 | X | X | X |

Ex.: Example
C. Ex.: Comparative Example

TABLE 3

| | resist A | resist B | resist C |
|---|---|---|---|
| prebaking temperature (° C.) | 80 | 100 | 135 |
| prebaking time (sec) | 120 | 90 | 90 |
| post-baking temperature (° C.) | 100 | 110 | 135 |
| post-baking time (sec) | 120 | 90 | 90 |
| film thickness (Å) | 7100 | 7200 | 4100 |

As understood from the above description, the developer of the present invention is excellent in the wettability of a non-soluble portion of a photoresist after exposure and the solubility of a soluble portion, and can form a fine photoresist pattern advantageously without fail.

Since the dissolving speed of the non-soluble portion is controlled effectively, the photoresist pattern after development can be caused to remain without fail and the pattern portion can be protected in the subsequent etching step without fail.

Particularly, the developer of the present invention can be used effectively as a developer for chemically amplifying photoresists.

1. A photoresist developer of an alkali aqueous solution which comprises a nonionic surfactant and a cationic surfactant in a total amount of 10 to 5,000 ppm by weight.

2. The photoresist developer of claim 1, wherein the weight ratio of the nonionic surfactant to the cationic surfactant is 5:95 to 95:5.

3. The photoresist developer of claim 1 or 2, wherein the photoresist is a chemically amplifying photoresist.

4. The photoresist developer of claim 1 or 2, wherein the nonionic surfactant is at least one nonionic surfactant selected from the group consisting of polyoxyethylene polyoxypropylene alkyl ethers, polyoxyethylene polyoxypropylene alkylphenyl ethers, polyoxyethylene polyoxypropylene glycols and polyoxyethylene polyoxypropylene alkylamides.

5. The photoresist developer of claim 1 or 2, wherein the cationic surfactant is at least one cationic surfactant selected from the group consisting of primary, secondary, tertiary and quaternary alkylamines and salts thereof, benzylpyridinium and salts thereof, alkylpyridiniums and salts thereof, and polyoxyethylene alkylbenzyl ammoniums and salts thereof.

6. The photoresist developer of claim 1 or 2, wherein the alkali aqueous solution is an alkali aqueous solution containing at least one alkali source selected from the group consisting of tetramethylammonium hydroxide and trimethyl(2-hydroxyethyl)ammonium hydroxide.
